(19) United States
(12) Patent Application Publication
(10) Pub. No.: US 2006/0148184 A1
(43) Pub. Date: Jul. 6, 2006

(54) Method for forming LDMOS channel

(76) Inventor: Woong Je Sung, Bucheon-city (KR)

Correspondence Address: MCKENNA LONG & ALDRIDGE LLP;Song K. Jung, 1900 K Street, N.W., Washington, DC, 20006, US

(21) Appl. No.: 11/320,774

(22) Filed: Dec. 30, 2005

(30) Foreign Application Priority Data
Dec. 31, 2004 (KR) 10-2004-0118489

(51) Int. Cl. H01L 21/336; H01L 21/425

(52) U.S. Cl. 438/301; 438/525

(57) ABSTRACT

A method of forming an LDMOS channel is provided. The method includes forming a conductive epitaxial layer on a semiconductor substrate, forming a photoresist pattern, implanting P-type and N-type ions with a first level of energy by using a tilt implantation method onto the semiconductor substrate, and implanting P-type ions with a second level of energy onto the semiconductor substrate. Accordingly, in an LDMOS channel forming process of the present invention, P-type and N-type ions are implanted using a tilt ion implantation method, and the LDMOS channel formed thereby is not affected by the subsequent P-type ion implantation having a high energy to form a p-body area. Therefore, a threshold voltage that is highly sensitive to a photoresist tilt can be uniformly maintained, and current asymmetry and Gm distortion which may occur due to a tilt difference of the photoresist can be prevented.

This application claims the benefit of Korean Application No. 10-2004-0118489, filed on Dec. 31, 2004, which is hereby incorporated by reference for all purposes as if fully set forth herein.

### BACKGROUND OF THE INVENTION

1. Field of the Invention

The present invention relates to a method of forming an LDMOS channel. More particularly, the present invention relates to an ion implantation method in which an LDMOS channel area is not affected by a boron concentration with a high energy in a p-body area. Thus, a threshold voltage that is highly sensitive to a photoresist tilt can be uniformly maintained.

2. Discussion of the Related Art

In the field of power integrated circuits, power transistors have been remarkably improved since a low “on-resistance” (RDSon) and a high breakdown voltage have been able to be implemented in a lateral double diffused MOS transistor (hereinafter, referred to as a LDMOS). The implementation is due to a reduced surface field technique by the use of a “high voltage thin layer device” (RESURF device), disclosed in the IEDM Technology Digest, pp. 238-241, J. A. Appels & H. M. J. Vaes, (1979).

A highly integrated power device having an analog function and a VLSI logic may be required in a future intelligent integrated circuit. A DMOS transistor is a significant element in a power device that can process a high voltage. The DMOS transistor has a current processing capability per a unit area or an on-resistance per a unit area. The on-resistance per a unit area can be reduced by reducing a cell area of a MOS device with respect to a predetermined rated voltage.

In the field of power transistors, a connection width between a polysilicon and a contact area which respectively form gate and source electrodes is defined as a cell pitch of the device. According to a related art relative to a DMOS power transistor, in order to reduce the width of a polysilicon area, the depth of a P-well junction has to be reduced. Here, a minimum junction depth is defined by a necessary breakdown voltage.

A related art LDMOS has been highly acceptable in a VLSI process due to its simple structure but has failed to be widely recognized because of its inferior capability compared to a vertical DMOS (VDMOS). Recently, a RESURF LDMOS having an excellent specific on-resistance has been introduced.

In a drain or source of a transistor to which a high voltage is directly applied, a punch-through voltage between the drain and the source and a semiconductor substrate, and a breakdown voltage between the drain and source and a well or a substrate, have to be greater than the aforementioned high voltage.

FIG. 1 is a sectional view of a related art LDMOS showing how the LDMOS channel is formed.

Referring to FIG. 1, shallow boron implantation, high energy boron implantation, and arsenic implantation are carried out on a semiconductor substrate 100 using the same photoresist pattern 110 as a mask. The shallow boron implantation and the arsenic implantation are performed for forming LDMOS channel. After implanting the ions, a diffusion process is performed. The shallowly-implanted boron and arsenic ions are aligned to form a short channel 120 while being diffused based on their own diffusion coefficient. The high energy boron implantation is carried out for decreasing the resistance of p-area 130 of the semiconductor substrate 100, thereby preventing parasitic NPN bipolar transistor from turning on. Although the boron ions implanted with high energy should not affect the LDMOS channel formation, they are also implanted at both sides of the short channel 120 due to the tilt of the photoresist pattern 110. This tilt changes the concentration of the short channel 120, thereby causing the threshold voltage variation. Furthermore, when using a source in both directions, Gm distortion may occur.

Thus, the boron ion implantation with a high energy, which is used for preventing a parasitic NPN bipolar transistor from turning on, may adversely affect a stable channel formation.

### SUMMARY OF THE INVENTION

Accordingly, the present invention is directed to a method for forming an LDMOS channel that substantially obviates one or more problems due to limitations and disadvantages of the related art.

An advantage of the present invention is to provide a method for forming an LDMOS channel that may constantly maintain a threshold voltage and prevent current asymmetry and Gm distortion.

Additional features and advantages of the invention will be set forth in the description which follows, and in part will be apparent from the description, or may be learned by practice of the invention. The objectives and other advantages of the invention will be realized and attained by the method particularly pointed out in the written description and claims hereof as well as the appended drawings.

To achieve these and other advantages and in accordance with the purpose of the present invention, as embodied and broadly described, a method of forming an LDMOS channel includes forming a photoresist pattern on a semiconductor substrate, implanting P-type and N-type ions with a first level of energy using a tilt implantation method onto the semiconductor substrate using the photoresist pattern as a mask, and implanting P-type ions with a second level of energy onto the semiconductor substrate using the photoresist pattern as a mask.

In another aspect of the present invention, the method further includes forming a conductive epitaxial layer on the semiconductor substrate before forming the photoresist pattern.

In another aspect of the present invention, the P-type ions include boron (B) ions.

In another aspect of the present invention, the N-type ions include arsenic (As) ions.

In another aspect of the present invention, the second level of energy is higher than the first level of energy.

In another aspect of the present invention, the method further includes annealing the ion-implanted semiconductor substrate for a diffusion process.

In another aspect of the present invention, the step of implanting P-type ions with the second level of energy is performed by a vertical implantation method.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a sectional view of a related art LDMOS showing how the LDMOS channel is formed; and

FIGS. 2A and 2B are sectional views of an LDMOS according to an embodiment of the present invention showing how the LDMOS channel is formed.

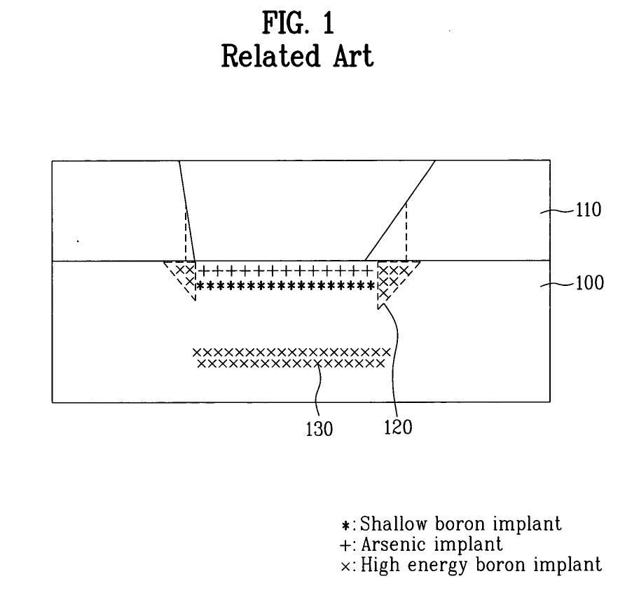

### DETAILED DESCRIPTION OF THE INVENTION

Reference will now be made in detail to embodiments of the present invention, examples of which are illustrated in the accompanying drawings. Wherever possible, like reference designations will be used throughout the drawings to refer to the same or similar parts.

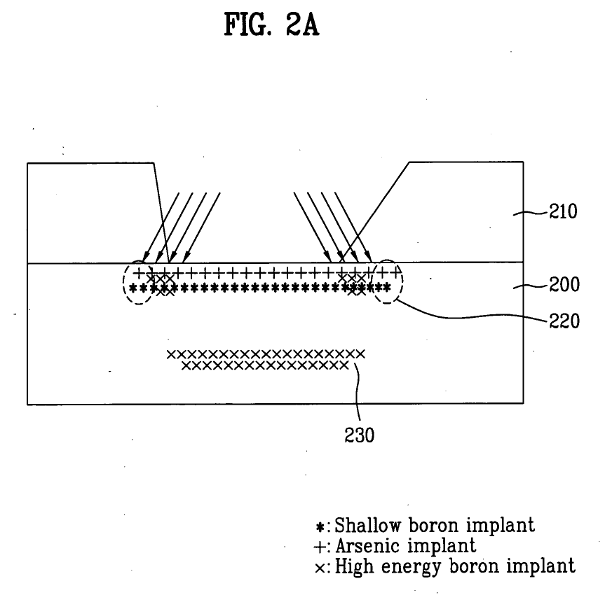

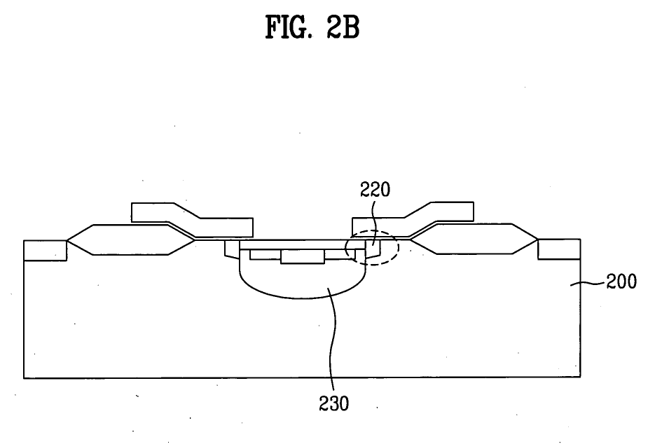

Referring to FIGS. 2A and 2B, a conductive epitaxial layer (not shown) is formed on a semiconductor substrate 200. Subsequently, a photoresist pattern 210 is formed on the conductive epitaxial layer exposing a portion of the epitaxial layer in which an LDMOS channel is to be formed. Using the photoresist pattern as a mask, P-type ions, which may be boron ions, and N-type ions, which may be arsenic ions, are implanted with a first level of energy onto the semiconductor substrate 200.

According to an exemplary embodiment of the present invention, the implantation with the first level of energy is carried out by using a tilt implantation method so that the P-type and N-type ions are implanted below the photoresist pattern 210 as well as the exposed area.

Then, the semiconductor substrate 200 is subject to an annealing process. During the annealing process, the implanted ions are diffused based on their own diffusion coefficients, thereby forming self-aligned channel 220.

The P-type ions, such as boron ions, are implanted with a second level of energy which is higher than the first level of energy onto the semiconductor substrate 200 to form a p-body area 230. The p-body area 230 is formed to prevent a parasitic NPN bipolar transistor from turning on.

According to the exemplary embodiment, the implantation with the second level of energy is carried out by means of a vertical implantation method where the implantation is performed in a vertical direction so that the implanted P-type ions do not affect the concentration of the ions previously implanted with the first level of energy below the photoresist pattern 210. That is, the ion implantation to form a p-body area 230 does not affect the LDMOS channel formation in the present invention.

Through the aforementioned process, a threshold voltage difference that can be caused by even a very small tilt difference of a photoresist 210 can be avoided, and a photolithography process margin can be ensured.

Accordingly, in an LDMOS channel forming process according to an exemplary embodiment of the present invention, boron and arsenic ions are implanted by using a tilt ion implantation method, and an LDMOS channel area is thereby isolated without being affected by a boron concentration implanted with a high energy to form a p-body area 230. In addition, a threshold voltage that is highly sensitive to a photoresist tilt can be uniformly maintained, and current asymmetry and Gm distortion which may occur due to a tilt difference of the photoresist can be prevented.

In addition, a photolithography process margin can be widely ensured, without considering a processing time, a pattern density for each product, and a photolithography processing apparatus.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A method of forming an LDMOS channel comprising:
forming a photoresist pattern on a semiconductor substrate;
implanting P-type and N-type ions with a first level of energy using a tilt implantation method onto the semiconductor substrate using the photoresist pattern as a mask; and
implanting P-type ions with a second level of energy onto the semiconductor substrate using the photoresist pattern as a mask.

2. The method of claim 1, further comprising:
forming a conductive epitaxial layer on the semiconductor substrate before forming the photoresist pattern.

3. The method of claim 1, wherein the P-type ions include boron ions.

4. The method of claim 1, wherein the N-type ions include arsenic ions.

5. The method of claim 1, wherein the second level of energy is higher than the first level of energy.

6. The method of claim 1, further comprising:
annealing the ion-implanted semiconductor substrate for a diffusion process.

7. The method of claim 1, wherein the step of implanting P-type ions with the second level of energy is performed by a vertical implantation method.
